(19) United States
(12) Patent Application Publication
(10) Pub. No.: US 2025/0338780 A1
(43) Pub. Date: Oct. 30, 2025

(54) FREE LAYER IN MAGNETIC TUNNEL JUNCTION OF A MRAM DEVICE

(71) Applicant: INTERNATIONAL BUSINESS MACHINES CORPORATION, ARMONK, NY (US)

(72) Inventors: MATTHIAS GEORG GOTTWALD, Ridgefield, CT (US); Guohan Hu, Yorktown Heights, NY (US); Alexander Reznicek, Troy, NY (US); Stephen L. Brown, Carmel, NY (US); GUKCHEON KIM, Dobbs Ferry, NY (US)

(21) Appl. No.: 18/650,502

(22) Filed: Apr. 30, 2024

(51) Int. Cl. H10N 50/85; H10B 61/00; H10N 50/01; H10N 50/10

(52) U.S. Cl. CPC H10N 50/85; H10B 61/00; H10N 50/01; H10N 50/10

(57) ABSTRACT

Embodiments of present invention provide a magnetoresistive random-access-memory (MRAM) device. The MRAM device includes a reference layer; a tunnel barrier layer next to the reference layer; and a free layer next to the tunnel barrier layer, where the free layer includes a crystalline AIMnGe layer in a C38 structure formed on a magnetic seed layer, and the magnetic seed layer is a crystallized MnCo₂Si layer or a crystallized MnCo₂Ge layer having a cubic Heusler structure with a (001) texture. A method of forming the MRAM device is also provided.

### BACKGROUND

The present application relates to manufacturing of semiconductor integrated circuits. More particularly, it relates to method of forming a free layer in a magnetic tunnel junction of a magnetoresistive random-access memory and the structure formed thereby.

Semiconductor memory devices are well recognized as playing an extreme important role in managing and organizing digital information which, in recent years, has experienced explosive growth and is constantly transforming our society. Magnetoresistive random-access memory (MRAM) is a type of non-volatile memory (NVM). Particularly a spin-transfer torque MRAM (STT-MRAM) is known as an embedded NVM (eNVM) that is capable of holding saved digital information without losing them even in the event that supply of power to the STT-MRAM device is down or accidentally cut off. The use of STT-MRAM enables faster switching time, higher densities, and lower power consumption.

Recently, STT-MRAM has been used in advanced application where fast switching time such as a switching time of less than 10 ns is required. For example, in order to replace embedded dynamic random-access-memory (eDRAM) or use as last level cache, STT-MRAM with a switching time around 2 ns may be required. STT-MRAM, like other MRAM technology, is based on a magnetic tunnel junction (MTJ) stack that usually includes a tunnel barrier layer that is placed or sandwiched between a reference layer and a free layer. In order to provide fast switch time, the MTJ stack needs to have a low moment and high magnetic anisotropy field. Manganese (Mn) based ordered magnetic alloys have been used in making the free layer in the MTJ stack with very high anisotropy field. However, MRAM arrays built from MTJ stacks with Mn-based ordered magnetic alloys suffer from wide retention distributions and intermediate resistance states, which consequently limits the size that the MRAM array may achieve and related performance of the MRAM array.

### SUMMARY

Embodiments of present invention provide a magnetoresistive random-access-memory (MRAM) device. The MRAM device includes a reference layer; a tunnel barrier layer of magnesium-oxide (MgO); and a free layer, where the free layer includes a crystalline AIMnGe layer on a magnetic seed layer, the magnetic seed layer including a ferromagnetic material and more than 45 at.% of cobalt (Co).

In one embodiment, the magnetic seed layer has a cubic Heusler structure with a (001) texture. In another embodiment, the magnetic seed layer is a crystallized MnCo2Si layer or a crystallized MnCo2Ge layer.

In one embodiment, the crystalline AIMnGe layer has a C38 structure. In another embodiment, the crystalline AIMnGe layer has a thickness between about 5 nm and about 8 nm and the magnetic seed layer has a thickness between about 1 nm and about 3 nm.

In one embodiment, the free layer further includes an interface layer between the crystalline AIMnGe layer and the magnetic seed layer, and the interface layer has a thickness ranging from about 0.5 nm to about 2 nm. In another embodiment, the interface layer has a cubic or tetragonal crystalline symmetry and contains elements of Al and Co.

In one embodiment, a first grain boundary along a film plane of the crystalline AIMnGe layer, a second grain boundary along a film plane of the magnetic seed layer, and a third grain boundary along a film plane of the interface layer are no further than 1 nm away from each other. In another embodiment, a grain size of the crystalline AIMnGe layer, the magnetic seed layer, and the interface layer, in their respective film planes, is between about 100 nm2 and about 500000 nm2.

According to one embodiment, the magnetic seed layer is a second seed layer, and the MRAM device further includes a first seed layer of MgO directly underneath the second seed layer, the first seed layer having a thickness between about 0.6 nm and about 2 nm.

According to another embodiment, the MRAM device further includes a spin polarizer layer between the crystalline AIMnGe layer and the tunnel barrier layer.

Embodiments of present invention provide a method of forming a magnetoresistive random-access-memory (MRAM) device. The method includes providing a bottom electrode; forming a first seed layer of magnesium-oxide (MgO) on top of the bottom electrode; forming a second seed layer of MnCo2Si or MnCo2Ge on top of the first seed layer; forming an ordered magnetic alloy (OMA) layer of AIMnGe alloy on top of the second seed layer; annealing the second seed layer to create a crystallized MnCo2Si or MnCo2Ge layer; annealing the OMA layer to create a crystalline AIMnGe layer; and forming a tunnel barrier layer on top of the OMA layer and a reference layer on top of the tunnel barrier layer to form a magnetic tunnel junction (MTJ) stack.

According to one embodiment, the method further includes patterning the MTJ stack into a MTJ pillar and forming a top electrode in contact with the MTJ pillar to form the MRAM device.

In one embodiment, annealing the second seed layer includes transforming the MnCo2Si or MnCo2Ge into a cubic Heusler structure with a (001) texture.

In another embodiment, annealing the OMA layer includes transforming the AIMnGe alloy into a C38 structure.

According to one embodiment, the method further includes forming a spin polarizer layer on top of the crystalline AIMnGe layer of OMA layer before forming the tunnel barrier layer.

### BRIEF DESCRIPTION OF THE DRAWINGS

The present invention will be understood and appreciated more fully from the following detailed description of embodiments of present invention, taken in conjunction with accompanying drawings of which:

FIG. 1 is a demonstrative illustration of cross-sectional view of a semiconductor structure according to one embodiment of present invention;

FIGS. 2-9 are demonstrative illustrations of cross-sectional views of a semiconductor structure at various stages of manufacturing thereof according to several embodiments of present invention; and

FIG. 10 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

Embodiments of present invention provide a structure of free layer that may be used in a MTJ stack for improved retention distribution of a MRAM array formed from the MTJ stack. The free layer includes a ferromagnetic seed layer underneath an ordered magnetic alloy layer which may be a manganese (Mn) based alloy layer. The ferromagnetic seed layer creates an exchange coupling bridge between grains of the Mn-based ordered magnetic alloy layer, which otherwise has a weak grain-to-grain exchange interaction. The enhancement of grain-to-grain exchange interaction in the Mn-based ordered magnetic alloy layer helps control the variability in retention between MRAM devices made from the free layer with Mn-based ordered magnetic alloy layer.

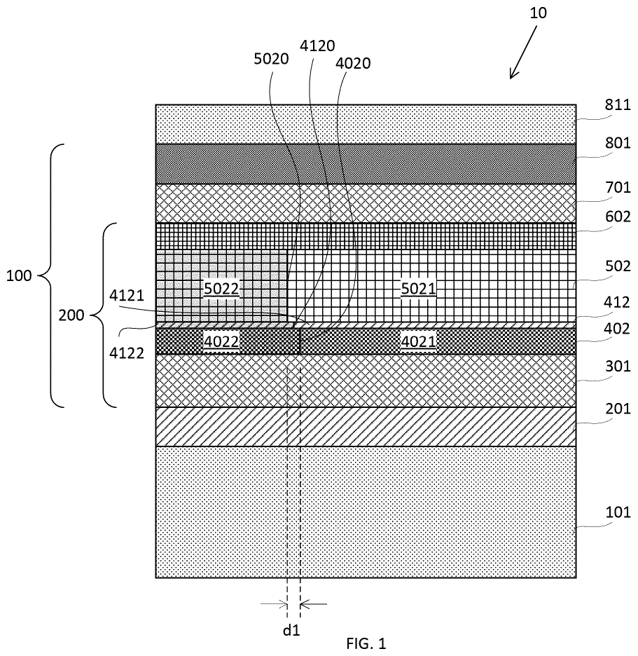

FIG. 1 is a demonstrative illustration of cross-sectional view of a semiconductor structure according to one embodiment of present invention. More particularly, embodiments of present invention provide a MRAM device 10 that includes a MTJ stack 100. The MTJ stack 100 may include a free layer 200, a tunnel barrier layer 701 on top of the free layer 200, and a reference layer 801 on top of the tunnel barrier layer 701. In one embodiment, the free layer 200 may include a first seed layer 301, a second seed layer 402 on top of the first seed layer 301, and an ordered magnetic alloy (OMA) layer 502 on top of the second seed layer 402. In another embodiment, the free layer 200 may additionally include a spin polarizer layer 602 on top of the OMA layer 502. The MRAM device 10 may further include a bottom electrode 101 with one or more diffusion barrier layers, such as a diffusion barrier layer 201, on top thereof. The free layer 200 may be on top of the bottom electrode 101 via the diffusion barrier layer 201. Some adhesion layers may be used between the free layer 200 and the diffusion barrier layer 201. The MRAM device 10 may also include a top electrode 811 on top of the reference layer 801.

With regard to the free layer 200, in one embodiment, the first seed layer 301 may be a layer of magnesium-oxide (MgO) that has a thickness ranging from about 0.6 nm to about 2 nm. The second seed layer 402 may be a layer of ferromagnetic material and thus as a magnetic seed layer and may have a cubic Heusler structure with a (001) texture. In one embodiment, the magnetic seed layer with the cubic Heusler structure may be a layer of crystallized MnCo₂Si or crystallized MnCo₂Ge. The crystallized MnCo₂Si or crystallized MnCo₂Ge layer may contain at least 30 at.% of cobalt (Co), preferably more than 45 at.% of Co, and may have a thickness ranging from about 1 nm to about 3 nm. The OMA layer 502 may be a layer of alloy having a C38 structure. For example, the OMA layer 502 may be a layer of AIMnGe alloy, or more particularly a layer of crystalline AIMnGe alloy. The crystalline AIMnGe layer may have a thickness ranging from about 2 nm to about 12 nm, and more typically from about 5 nm to about 8 nm. An interface layer 412 may exist between the OMA layer 502 and the second seed layer 402. The interface layer 412 may have a cubic or tetragonal crystalline symmetry and contain elements from the OMA layer 502 and the second seed layer 402 such as, for example, Al and Co. The interface layer 412 may have a thickness ranging from about 0.5 nm to about 2 nm.

In one embodiment, there may exist a first grain boundary 5020 in a film plane of the OMA layer 502 between a first area 5021 and a second area 5022, a second grain boundary 4020 in a film plane of the second seed layer 402 between a first area 4021 and a second area 4022, and a third grain boundary 4120 in a film plane of the interface layer 412 between a first area 4121 and a second area 4122. The first, second, and third grain boundaries 5020, 4020, and 4120 may be vertically substantially aligned to be known as being coherent with each other. In other words, a horizontal distance d1 among the first, the second, and the third grain boundary 5020, 4020, and 4120 of the OMA layer 502, the second seed layer 402, and the interface layer 412 may be no further than 1 nm. Here, the distance d1 is measured horizontally along the film planes, which are perpendicular to a vertical film growth direction.

In one embodiment, the optional spin polarizer layer 602 may be a layer of material with high spin polarization such as a layer of crystallized MnCo₂Si or MnCo₂Ge. The spin polarizer layer 602 may have a thickness ranging from about 0.2 nm to about 2 nm and more preferably between about 0.4 nm and about 0.8 nm. The spin polarizer layer 602 may be applied here to increase spin polarization at the interface with the tunnel barrier layer 701 of MgO, while a thickness of the spin polarizer layer 602 is kept at minimal to maintain a relatively low moment for fast write time of the MRAM device.

According to one embodiment of present invention, the OMA layer 502, such as the crystalline AIMnGe layer, may have a thickness that is about 35% or more of a combined total thickness of the free layer 200. For example, the free layer 200 may have a thickness ranging from about 7 nm to about 13 nm, and the OMA layer 502 may have a thickness equal to or larger than 5 nm. By the nature of the processes that the OMA layer 502 is formed on top of the second seed layer 402, as being described below in more details, there is an epitaxial relationship between the grain of the crystalline AIMnGe layer of the OMA layer 502, the grain of the interface layer 412, and the grain of the crystallized MnCo₂Si or MnCo₂Ge layer of the second seed layer 402. In other words, the grain size of the OMA layer 502 of the crystalline AIMnGe layer may be decided by or derived from the grain size of the second seed layer 402 of the crystallized MnCo₂Si or MnCo₂Ge layer. For example, grain boundaries in the film plane of the OMA layer 502 of the crystalline AIMnGe layer, grain boundaries in the film plane of the second seed layer 402 of crystallized MnCo₂Si or MnCo₂Ge layer, and grain boundaries in the film plane of the interface layer 412 may be coherent with each other, vertically substantially aligned respectively, and no further than 1 nm horizontally away from each other. In other words, a distance d1 among the grain boundaries of respective layers may be less than 1 nm. Moreover, the crystalline AIMnGe layer may be in a C38 structure with a (001) texture and its long axis may be perpendicular to a film plane of the underneath crystallized MnCo₂Si or MnCo₂Ge layer of the second seed layer 402.

The tunnel barrier layer 701 may be a MgO layer having a thickness ranging from about 0.8 nm to about 1.5 nm. The reference layer 801 may generally have a multilayer structure with crystallized CoFe alloy. Both the bottom electrode 101 and the top electrode 811 may be a layer of conductive material such as, for example, tungsten (W), cobalt (Co), aluminum (Al), copper (Cu), or other suitable conductive materials.

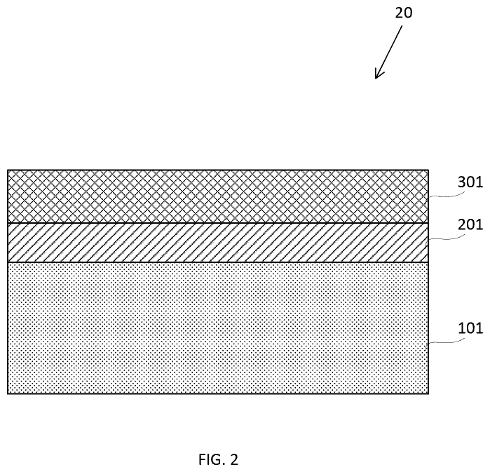

FIGS. 2-9 are demonstrative illustrations of cross-sectional views of a semiconductor structure at various stages of manufacturing thereof according to several embodiments of present invention. More particularly, embodiments of present invention provide forming a MRAM device 20 by receiving or providing a bottom electrode 101 and forming a diffusion barrier layer 201 on top of the bottom electrode 101. The bottom electrode 101 may be a layer of conductive material including, for example, W, Co, Al, Cu, or other suitable conductive materials. The diffusion barrier layer 201 may be a layer of amorphous tantalum (Ta) and/or tantalum-nitride (TaN). After forming the diffusion barrier layer 201 on top of the bottom electrode 101, a first seed layer 301 may be formed through, for example, a deposition process such as a physical-vapor-deposition (PVD) process on the diffusion barrier layer 201. However, embodiments of present invention are not limited in this aspect and other deposition processes such as a chemical-vapor-deposition (CVD) process or an atomic-layer-deposition (ALD) process may be used as well. As is demonstratively illustrated in FIG. 2, in one embodiment, the first seed layer 301 may be a layer of magnesium-oxide (MgO) material that has a thickness ranging from about 0.6 nm to about 2 nm.

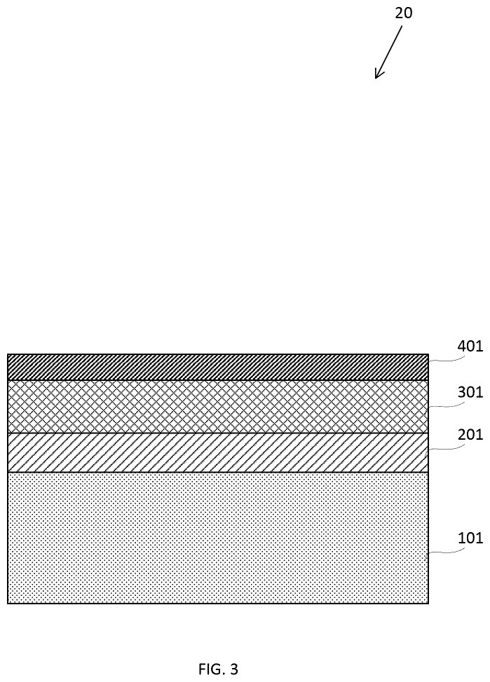

FIG. 3 is a demonstrative illustration of cross-sectional view of a semiconductor structure at a step of manufacturing thereof according to one embodiment of present invention. More particularly, following the step illustrated in FIG. 2, embodiments of present invention provide forming a second seed layer 401 through, for example, a PVD deposition process on top of the first seed layer 301 such that the first seed layer 301 is directly underneath the second seed layer 401. Other deposition processes may be used as well. The second seed layer 401 may be a layer of ferromagnetic material such as, for example, a layer of MnCo₂Si or MnCo₂Ge. The MnCo₂Si layer or the MnCo₂Ge layer may be formed to contain at least 30 at.% of cobalt (Co), preferably more than 45 at.% of Co, and may be deposited to have a thickness ranging from about 1 nm to about 3 nm. The thickness of the MnCo₂Si or MnCo₂Ge layer may be made thick enough such that it remains as a continuous layer after being subsequently subjected to an annealing process, as being described below in more details. However, the MnCo₂Si or MnCo₂Ge layer is not made too thick to cause adding too much moment and creating in-plane anisotropy.

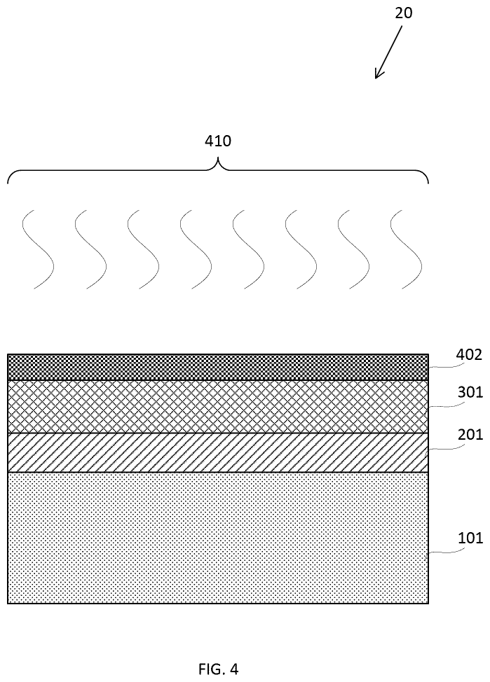

FIG. 4 is a demonstrative illustration of cross-sectional view of a semiconductor structure at a step of manufacturing thereof according to one embodiment of present invention. More particularly, following the step illustrated in FIG. 3, embodiments of present invention provide performing an in-situ anneal process 410 to crystallize the second seed layer 401. For example, the second seed layer 401, such as the layer of MnCo₂Si or MnCo₂Ge, may be subjected to an annealing environment with a temperature around 300 to 450 degrees Celsius (C) for a duration of about 5 to 60 minutes. The annealing process may cause the MnCo₂Si layer or the MnCo₂Ge layer to become a second seed layer 402 of highly crystallized MnCo₂Si or highly crystallized MnCo₂Ge. As a result, the second seed layer 402 of highly crystallized MnCo₂Si or highly crystallized MnCo₂Ge may have a cubic Heusler structure with a (001) texture. This highly crystallized MnCo₂Si layer or highly crystallized MnCo₂Ge layer enables a crystallized ordered magnetic alloy (OMA) layer, such as a crystalline AIMnGe layer with a C38 structure, to be formed on top the second seed layer 402 as being described below in more details.

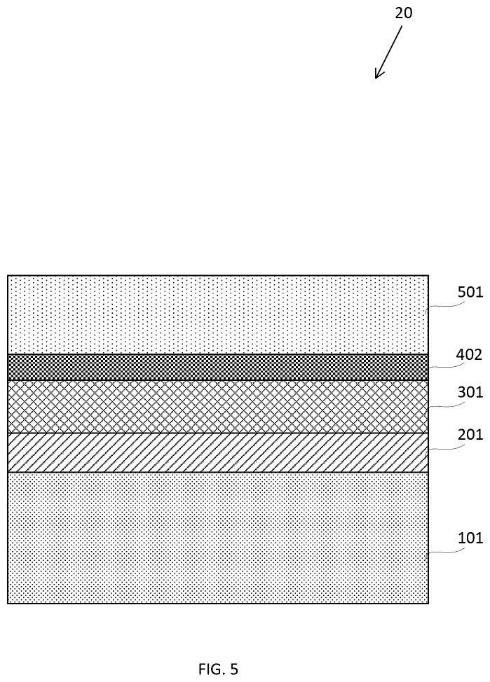

FIG. 5 is a demonstrative illustration of cross-sectional view of a semiconductor structure at a step of manufacturing thereof according to one embodiment of present invention. More particularly, following the step illustrated in FIG. 4, embodiments of present invention provide forming an ordered magnetic alloy (OMA) layer 501 on top of the second seed layer 402. For example, a layer of AIMnGe alloy may be formed through a deposition process such as, for example, a PVD process on top of the crystallized MnCo₂Si or MnCo₂Ge layer to have a thickness ranging from about 2 nm to about 12 nm, preferably from about 5 nm to about 8 nm. Other deposition processes may be used as well.

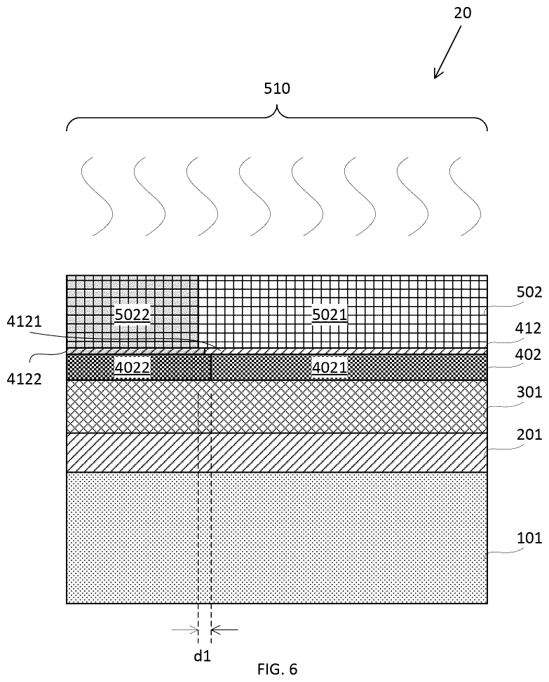

FIG. 6 is a demonstrative illustration of cross-sectional view of a semiconductor structure at a step of manufacturing thereof according to one embodiment of present invention. More particularly, following the step illustrated in FIG. 5, embodiments of present invention provide, though optional at this stage, applying an annealing process 510 to cause crystallization of the AIMnGe alloy and transform the AIMnGe alloy into a C38 structure. For example, the AIMnGe alloy of the OMA layer 501 may be subjected to the annealing process 510 under a temperature about 300 to 450 degrees Celsius for a duration of about 5 to 60 minutes. The AIMnGe alloy of the OMA layer 501 may thus be transformed into a crystalline AIMnGe layer of a crystallized OMA layer 502.

The annealing process may also create an interface layer 412 between the second seed layer 402 and the crystallized OMA layer 502. More particularly, the interface layer 412 may have a thickness around 0.5 nm to 2 nm, a cubic or tetragonal crystalline symmetry, and may contain elements such as Al, Mn, and Ge from the crystallized OMA layer 502, and elements such as Co from the second seed layer 402. More importantly, the interface layer 412 may create or result in an epitaxial relationship, in grain sizes and positioning, between the second seed layer 402 of highly crystallized MnCo₂Si or MnCo₂Ge and the crystallized OMA layer 502 of crystalline AIMnGe layer. In other words, the grain size of the crystalline AIMnGe layer of the crystallized OMA layer 502 may be predicted, influenced, and/or decided by the grain size of the crystallized MnCo₂Si or MnCo₂Ge layer of the second seed layer 402. In one embodiment, a grain size of the crystallized OMA layer 502, the second seed layer 402, and the interface layer 412, measured in film planes of the respective layers, may be between about 100 nm² and about 500000 nm². Moreover, the crystalline AIMnGe layer may have a C38 structure with a (001) texture, and the long axis of the C38 structure may be perpendicular to a film plane that is along the top surface of the second seed layer 402. In other words, the (001) texture of the crystalline AIMnGe layer of the crystallized OMA layer 502 may be influenced by the (001) texture of the highly crystallized MnCo₂Si or MnCo₂Ge of the second seed layer 402.

For Mn-based ordered magnetic alloys such as AIMnGe or Mn3Ge, grain-to-grain exchange interaction is usually very weak, such as between grains in a first area 5021 and grains in a second area 5022 of the crystallized OMA layer 502. In order to increase the exchange interaction among grains of the AIMnGe alloy, thereby reducing retention distribution and intermediate resistance states, embodiments of present invention provide forming the magnetic second seed layer 402 of ferromagnetic material such as crystallized MnCo₂Si or MnCo₂Ge layer underneath the AIMnGe alloy of the OMA layer 501. On the one hand, by applying an annealing process, the crystallized MnCo₂Si or MnCo₂Ge layer of the second seed layer 402 provides strong grain-to-grain exchange interaction among grains of the second seed layer 402 itself. On the other hand, the crystallized MnCo₂Si or MnCo₂Ge layer of the second seed layer 402 also provides strong exchange coupling with the crystalline AIMnGe layer on top of the second seed layer 402 because of the epitaxial relationship in grain sizes between the crystallized OMA layer 502 and the second seed layer 402.

For example, grains in the first area 5021 of the OMA layer 502 may have a strong exchange coupling with grains in a first area 4021 of the second seed layer 402. Similarly, grains in the second area 5022 of the OMA layer 502 may have a strong exchange coupling with grains in a second area 4022 of the second seed layer 402. Even though due to being a Mn-based OMA layer 502, grain-to-grain exchange interaction between grains in the first and the second area 5021 and 5022 may be weak, because of the strong exchange coupling among grains in the first and the second area 4021 and 4022 of the second seed layer 402, the weakness in exchange interaction between grains in the first and the second area 5021 and 5022 may be partially compensated via a first area 4121 of the interface layer 412 between the first area 5021 and the first area 4021, through the exchange coupling between grains in the first and the second area 4021 and 4022, and via a second area 4122 of the interfacing layer 412 between the second area 4022 and the second area 5022. In other words, the second seed layer 402, through the strong exchange coupling among its grains, provides an exchange coupling bridge between the first area 5021 and the second area 5022 of the OMA layer 502 of crystalline AIMnGe layer. A first grain boundary 5020 between the first and the second area 5021 and 5022, a second grain boundary 4020 between the first and the second area 4021 and 4022, and a third grain boundary 4120 between the first and the second area 4121 and 4122 may be vertically substantially aligned, with a distance d1 among the three boundaries being no further than 1 nm.

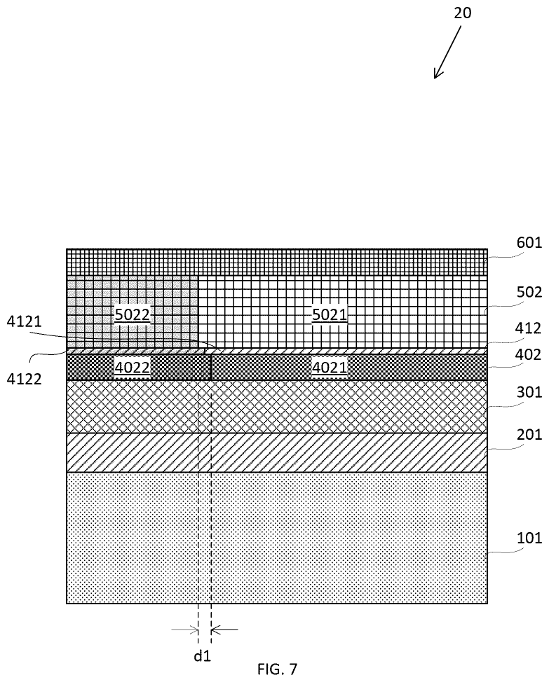

FIG. 7 is a demonstrative illustration of cross-sectional view of a semiconductor structure at a step of manufacturing thereof according to one embodiment of present invention. More particularly, following the step illustrated in FIG. 6, embodiments of present invention provide optionally forming or depositing a spin polarizer layer 601 on top of the OMA layer 502 for enhanced device performance. In one embodiment, the spin polarizer layer 601 may be a layer of MnCo₂Si, MnCo₂Ge, Co, a combination thereof, or a layer of material having high spin polarization. The spin polarizer layer 601 may be deposited to have a thickness around, for example, 0.5 nm to 1 nm.

It is noted here that, so far individual layers, such as the first seed layer 301, the second seed layer 401, the OMA layer 501, and the optional spin polarizer layer 601 may have been described as if they are formed separately, in fact some of them or all of them may be formed together and in-situ in, for example, a same PVD cluster tool or chamber using one or more targets or a combination of different targets.

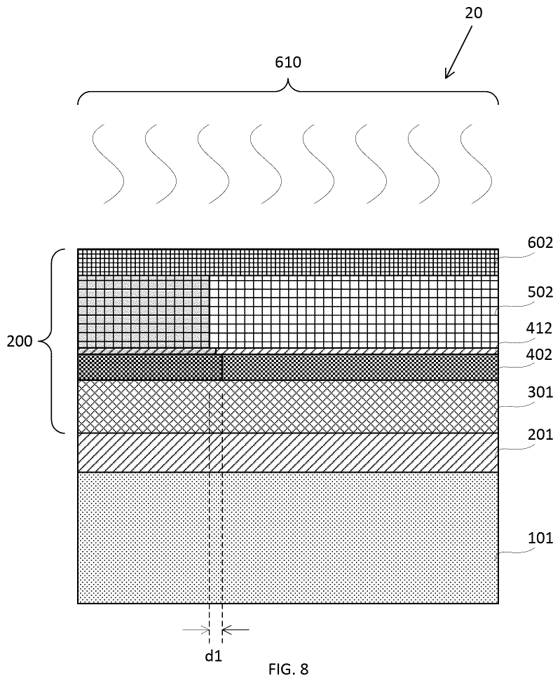

FIG. 8 is a demonstrative illustration of cross-sectional view of a semiconductor structure at a step of manufacturing thereof according to one embodiment of present invention. More particularly, following the step illustrated in FIG. 7, embodiments of present invention provide applying an annealing process 610 to crystallize the material of the spin polarizer layer 601, such as MnCo₂Si or MnCo₂Ge, thereby transforming the spin polarizer layer 601 into a crystallized spin polarizer layer 602. It is to be noted here that, since the annealing process 610 is applied here to anneal the spin polarizer layer 601, the previous annealing process 510 used in crystallizing the OMA layer 501 of AIMnGe alloy, as being demonstratively illustrated in FIG. 6, may be saved or become optional. Instead, the annealing process 610 used here may also be used to crystallize the OMA layer 501 of AIMnGe alloy. The crystallized spin polarizer layer 602 may also have one or more grain boundaries in its film planes, and these one or more grain boundaries may correspond to grain boundaries of the OMA layer 502, the interface layer 412, and the second seed layer 402.

The first seed layer 301, the second seed layer 402 including the interface layer 412 on top thereof, the OMA layer 502, and, when being used, the spin polarizer layer 602 together form a free layer 200. In one embodiment, the OMA layer 502 of crystalline AIMnGe layer may have a thickness that is equal to or more than 35% of a thickness of the free layer 200. For example, the crystalline AIMnGe layer of the OMA layer 502 may have a thickness ranging from about 5 nm to about 8 nm, while the free layer 200 may have a thickness ranging from about 7 nm to about 13 nm.

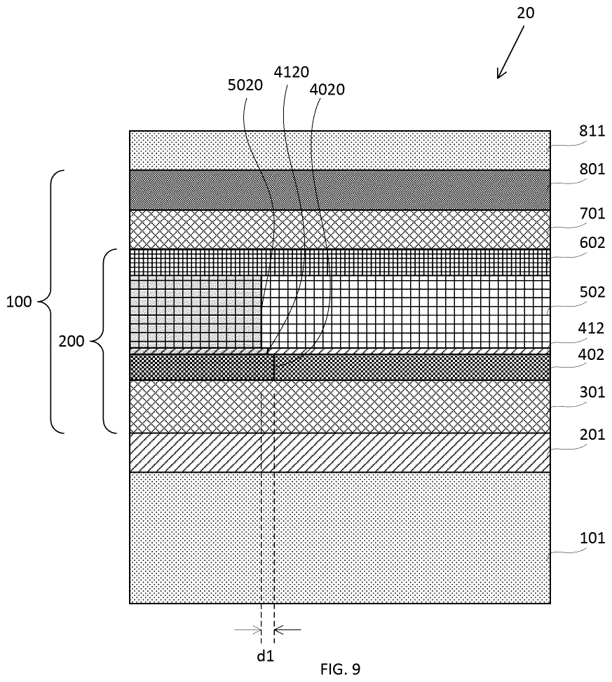

FIG. 9 is a demonstrative illustration of cross-sectional view of a semiconductor structure at a step of manufacturing thereof according to one embodiment of present invention. More particularly, following the step illustrated in FIG. 8, embodiments of present invention provide forming, for example through a deposition process, a tunnel barrier layer 701 next to and on top of the free layer 200 and more particularly on top of the OMA layer 502. In situations where a spin polarizer layer is used, the tunnel barrier layer 701 may be formed or deposited on top of the OMA layer 502 via the spin polarizer layer 602. In one embodiment, the tunnel barrier layer 701 may be a layer of magnesium-oxide (MgO) and may be formed to have a thickness ranging from about 0.8 nm to about 1.5 nm. Subsequently, a reference layer 801, which may be a CoFe alloy and in a multi-layer structure, may be deposited on top of the tunnel barrier layer 701. The reference layer 801, the tunnel barrier layer 701, and the free layer 200 together form a magnetic tunnel junction (MTJ) stack 100.

Additionally, a top electrode 811 may be formed next to and on top of the reference layer 801 in contact with the MTJ stack 100. The top electrode 811, the MTJ stack 100, and the bottom electrode 101 together form the MRAM device 20. The top electrode 811 may be a layer of conductive material of, for example, W, Cu, Co, Al or other suitable materials, similar to that of the bottom electrode 101.

Although not being explicitly illustrated in the above drawings, it is to be noted here that one or more lithographic patterning processes may be applied at this step and/or between any previous steps, to pattern the MTJ stack 100 and thereby transforming the MTJ stack 100 into one or more MTJ pillars. The MTJ pillars are then applied in forming one or more MRAM devices such as an array of MRAM devices. Because of the enhanced or improved grain-to-grain exchange interaction among grains at different areas of the OMA layer 502 of the crystalline AIMnGe layer, through the exchange coupling bridge provided by the second seed layer 402 underneath the OMA layer 502, the array of MRAM devices made from the free layer 200 having the OMA layer 502 achieves reduced retention distribution and intermediate resistance states.

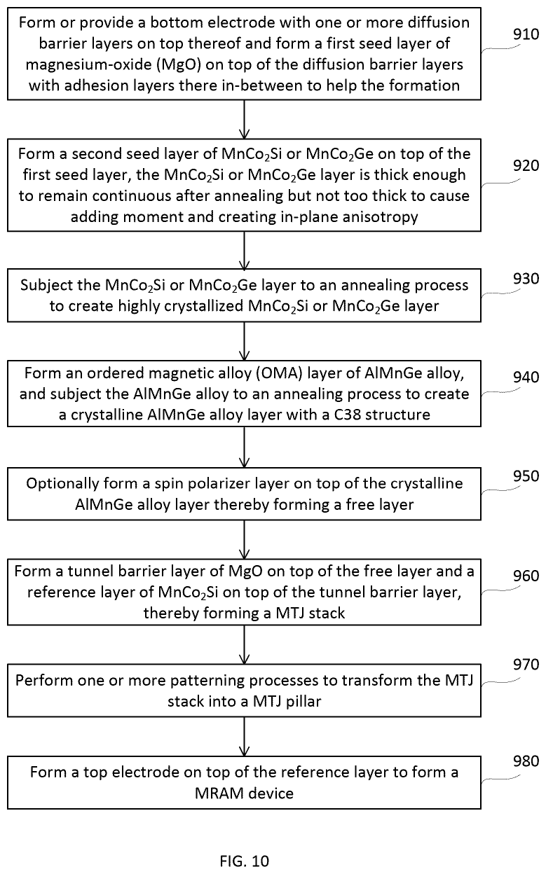

FIG. 10 is a simplified flow-chart of a method of forming a free layer of a MTJ of a MRAM device according to embodiments of present invention. More particularly, embodiments of present invention provide: (910) forming or providing a bottom electrode with one or more diffusion barrier layers on top thereof and forming a first seed layer of magnesium-oxide (MgO) on top of the diffusion barrier layers with adhesion layers there in-between to help the formation; (920) forming a second seed layer of MnCo₂Si or MnCo₂Ge on top of the first seed layer, the MnCo₂Si or MnCo₂Ge layer is thick enough to remain continuous after annealing but not too thick to cause adding moment and creating in-plane anisotropy; (930) subjecting the MnCo₂Si or MnCo₂Ge layer to an annealing process to create highly crystallized MnCo₂Si or MnCo₂Ge layer; (940) forming an ordered magnetic alloy (OMA) layer of AIMnGe alloy, and subjecting the AIMnGe alloy to an annealing process to create a crystalline AIMnGe layer with a C38 structure; (950) optionally forming a spin polarizer layer on top of the crystalline AIMnGe layer thereby forming a free layer; (960) forming a tunnel barrier layer of MgO on top of the free layer and a reference layer of MnCo₂Si or MnCo₂Ge on top of the tunnel barrier layer, thereby forming a MTJ stack; (970) performing one or more patterning processes to transform the MTJ stack into a MTJ pillar; and (980) forming a top electrode on top of the reference layer to form a MRAM device.

Various examples may possibly be described by one or more of the following features in the following numbered clauses:

Clause 1: A magnetoresistive random-access-memory (MRAM) device comprising: a reference layer; a tunnel barrier layer of magnesium-oxide (MgO); and a free layer, wherein the free layer comprises a crystalline AIMnGe layer on a magnetic seed layer, the magnetic seed layer comprising a ferromagnetic material and more than 45 at.% of cobalt (Co).

Clause 2: The MRAM device of clause 1, wherein the magnetic seed layer has a cubic Heusler structure with a (001) texture.

Clause 3: The MRAM device of clause 1, wherein the magnetic seed layer is a crystallized MnCo2Si layer or a crystallized MnCo2Ge layer.

Clause 4: The MRAM device of clause 1, wherein the crystalline AIMnGe layer has a C38 structure.

Clause 5: The MRAM device of clause 1, wherein the crystalline AIMnGe layer has a thickness between about 5 nm and about 8 nm and the magnetic seed layer has a thickness between about 1 nm and about 3 nm.

Clause 6: The MRAM device of clause 1, wherein the free layer further comprises an interface layer between the crystalline AIMnGe layer and the magnetic seed layer, and the interface layer has a thickness ranging from about 0.5 nm to about 2 nm.

Clause 7: The MRAM device of clause 6, wherein the interface layer has a cubic or tetragonal crystalline symmetry and contains elements of Al and Co.

Clause 8: The MRAM device of clause 6, wherein a first grain boundary along a film plane of the crystalline AIMnGe layer, a second grain boundary along a film plane of the magnetic seed layer, and a third grain boundary along a film plane of the interface layer are no further than 1 nm away from each other.

Clause 9: The MRAM device of clause 6, wherein a grain size of the crystalline AIMnGe layer, the magnetic seed layer, and the interface layer, in their respective film planes, is between about 100 nm2 and about 500000 nm2.

Clause 10: The MRAM device of clause 1, wherein the magnetic seed layer is a second seed layer, further comprises a first seed layer of MgO directly underneath the second seed layer, the first seed layer having a thickness between about 0.6 nm and about 2 nm.

Clause 11: The MRAM device of clause 1, further comprising a spin polarizer layer between the crystalline AIMnGe layer and the tunnel barrier layer.

Clause 12: A method of forming a magnetoresistive random-access-memory (MRAM) device, the method comprising: providing a bottom electrode; forming a first seed layer of magnesium-oxide (MgO) on top of the bottom electrode; forming a second seed layer of MnCo2Si or MnCo2Ge on top of the first seed layer; forming an ordered magnetic alloy (OMA) layer of AIMnGe alloy on top of the second seed layer; annealing the second seed layer to create a crystallized MnCo2Si or MnCo2Ge layer; annealing the OMA layer to create a crystalline AIMnGe layer; and forming a tunnel barrier layer on top of the OMA layer and a reference layer on top of the tunnel barrier layer to form a magnetic tunnel junction (MTJ) stack.

Clause 13: The method of clause 12, further comprising patterning the MTJ stack into a MTJ pillar and forming a top electrode in contact with the MTJ pillar to form the MRAM device.

Clause 14: The method of clause 12, wherein annealing the second seed layer comprises transforming the MnCo2Si or MnCo2Ge into a cubic Heusler structure with a (001) texture.

Clause 15: The method of clause 12, wherein annealing the OMA layer comprises transforming the AIMnGe alloy into a C38 structure.

Clause 16: The method of clause 12, further comprising forming a spin polarizer layer on top of the crystalline AIMnGe layer of OMA layer before forming the tunnel barrier layer.

Clause 17: A magnetoresistive random-access-memory (MRAM) device comprising: a reference layer; a tunnel barrier layer next to the reference layer; and a free layer next to the tunnel barrier layer, wherein the free layer comprises a crystalline AIMnGe layer in a C38 structure formed on a magnetic seed layer, and the magnetic seed layer is a crystallized MnCo2Si layer or a crystallized MnCo2Ge layer having a cubic Heusler structure with a (001) texture.

Clause 18: The MRAM device of clause 17, wherein the free layer further comprises an interface layer between the crystalline AIMnGe layer and the magnetic seed layer, the interface layer having a cubic or tetragonal crystalline symmetry and contains elements of Al and Co.

Clause 19: The MRAM device of clause 18, wherein a first grain boundary along a film plane of the crystalline AIMnGe layer, a second grain boundary along a film plane of the magnetic seed layer, and a third grain boundary along a film plane of the interface layer are no further than 1 nm away from each other.

Clause 20: The MRAM device of clause 17, wherein the free layer further comprises a spin polarizer layer between the crystalline AIMnGe layer and the tunnel barrier layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A magnetoresistive random-access-memory (MRAM) device comprising:
a reference layer;
a tunnel barrier layer of magnesium-oxide (MgO); and
a free layer,
wherein the free layer comprises a crystalline AIMnGe layer on a magnetic seed layer, the magnetic seed layer comprising a ferromagnetic material and more than 45 at.% of cobalt (Co).

2. The MRAM device of claim 1, wherein the magnetic seed layer has a cubic Heusler structure with a (001) texture.

3. The MRAM device of claim 1, wherein the magnetic seed layer is a crystallized MnCo₂Si layer or a crystallized MnCo₂Ge layer.

4. The MRAM device of claim 1, wherein the crystalline AIMnGe layer has a C38 structure.

5. The MRAM device of claim 1, wherein the crystalline AIMnGe layer has a thickness between about 5 nm and about 8 nm and the magnetic seed layer has a thickness between about 1 nm and about 3 nm.

6. The MRAM device of claim 1, wherein the free layer further comprises an interface layer between the crystalline AIMnGe layer and the magnetic seed layer, and the interface layer has a thickness ranging from about 0.5 nm to about 2 nm.

7. The MRAM device of claim 6, wherein the interface layer has a cubic or tetragonal crystalline symmetry and contains elements of Al and Co.

8. The MRAM device of claim 6, wherein a first grain boundary along a film plane of the crystalline AIMnGe layer, a second grain boundary along a film plane of the magnetic seed layer, and a third grain boundary along a film plane of the interface layer are no further than 1 nm away from each other.

9. The MRAM device of claim 6, wherein a grain size of the crystalline AIMnGe layer, the magnetic seed layer, and the interface layer, in their respective film planes, is between about 100 nm² and about 500000 nm².

10. The MRAM device of claim 1, wherein the magnetic seed layer is a second seed layer, further comprises a first seed layer of MgO directly underneath the second seed layer, the first seed layer having a thickness between about 0.6 nm and about 2 nm.

11. The MRAM device of claim 1, further comprising a spin polarizer layer between the crystalline AIMnGe layer and the tunnel barrier layer.

12. A method of forming a magnetoresistive random-access-memory (MRAM) device, the method comprising:
providing a bottom electrode;
forming a first seed layer of magnesium-oxide (MgO) on top of the bottom electrode;
forming a second seed layer of MnCo₂Si or MnCo₂Ge on top of the first seed layer;
forming an ordered magnetic alloy (OMA) layer of AIMnGe alloy on top of the second seed layer;
annealing the second seed layer to create a crystallized MnCo₂Si or MnCo₂Ge layer;
annealing the OMA layer to create a crystalline AIMnGe layer; and
forming a tunnel barrier layer on top of the OMA layer and a reference layer on top of the tunnel barrier layer to form a magnetic tunnel junction (MTJ) stack.

13. The method of claim 12, further comprising patterning the MTJ stack into a MTJ pillar and forming a top electrode in contact with the MTJ pillar to form the MRAM device.

14. The method of claim 12, wherein annealing the second seed layer comprises transforming the MnCo₂Si or MnCo₂Ge into a cubic Heusler structure with a (001) texture.

15. The method of claim 12, wherein annealing the OMA layer comprises transforming the AIMnGe alloy into a C38 structure.

16. The method of claim 12, further comprising forming a spin polarizer layer on top of the crystalline AIMnGe layer of OMA layer before forming the tunnel barrier layer.

17. A magnetoresistive random-access-memory (MRAM) device comprising:
a reference layer;
a tunnel barrier layer next to the reference layer; and
a free layer next to the tunnel barrier layer,
wherein the free layer comprises a crystalline AIMnGe layer in a C38 structure formed on a magnetic seed layer, and the magnetic seed layer is a crystallized MnCo₂Si layer or a crystallized MnCo₂Ge layer having a cubic Heusler structure with a (001) texture.

18. The MRAM device of claim 17, wherein the free layer further comprises an interface layer between the crystalline AIMnGe layer and the magnetic seed layer, the interface layer having a cubic or tetragonal crystalline symmetry and contains elements of Al and Co.

19. The MRAM device of claim 18, wherein a first grain boundary along a film plane of the crystalline AIMnGe layer, a second grain boundary along a film plane of the magnetic seed layer, and a third grain boundary along a film plane of the interface layer are no further than 1 nm away from each other.

20. The MRAM device of claim 17, wherein the free layer further comprises a spin polarizer layer between the crystalline AIMnGe layer and the tunnel barrier layer.
